(19) United States
(12) Patent Application Publication
(10) Pub. No.: US 2011/0159681 A1
(43) Pub. Date: Jun. 30, 2011

(54) Nonvolatile Memory Device and Method of Manufacturing the Same

(75) Inventors: Sung Min Hwang, Icheon-si (KR); Hyeon Soo Kim, Icheon-si (KR)

(73) Assignee: HYNIX SEMICONDUCTOR INC., Icheon-si (KR)

(21) Appl. No.: 12/973,278

(22) Filed: Dec. 20, 2010

(30) Foreign Application Priority Data
Dec. 30, 2009 (KR) 10-2009-134118

(51) Int. Cl. H01L 21/28

(52) U.S. Cl. 438/594; 257/E21.209

(57) ABSTRACT

A method of manufacturing a nonvolatile memory device includes forming a tunnel insulating layer over a semiconductor substrate, forming tunnel insulating patterns to expose portions of the semiconductor substrate by removing portions of the tunnel insulating layer formed over isolation regions of the semiconductor substrate, forming a first conductive layer of single crystalline material over the tunnel insulating patterns and exposed portions of the semiconductor substrate, and forming a second conductive layer over the first conductive layer.

### CROSS-REFERENCE TO RELATED APPLICATION

Priority to Korean patent application number 10-2009-0134118 filed Dec. 30, 2009, the entire disclosure of which is incorporated by reference herein, is claimed.

### BACKGROUND

An exemplary embodiment relates generally to a method of manufacturing a nonvolatile memory device and more particularly, to a method of manufacturing the floating gates of a nonvolatile memory device.

A NAND flash memory device (i.e., a nonvolatile memory device) includes a plurality of memory cells coupled in series to form a unit string. The use of NAND flash memory devices to replace other memory sticks, Universal Serial Bus (USB) drivers, and hard disks and the applications thereof are growing and widening.

To improve the uniformity of a threshold voltage distribution of a conventional nonvolatile memory cell, a floating gate is formed of a first conductive layer and a second conductive layer. For example, the first conductive layer may be formed of an undoped polysilicon layer, and the second conductive layer may be formed of a doped polysilicon layer. In the case of the undoped polysilicon layer, a small oxide valley is formed because the undoped polysilicon layer has a smaller grain size than the doped polysilicon layer, and low Fowler-Nordheim (FN) current is generated because of the small oxide valley. However, since the number of oxide valleys per unit area may increase, a shift in the FN current according to a variation in the active critical dimension is more uniform in nano-grain polysilicon having a smaller grain size than in common polysilicon. However, even though nano-grain polysilicon may be used, there is a difference in the FN tunneling current according to the grain size, which leads to irregularities in the threshold voltage and electrical characteristics of a nonvolatile memory cell.

### BRIEF SUMMARY

An exemplary embodiment relates to a method of manufacturing a nonvolatile memory device, which is capable of improving the electrical characteristics of the nonvolatile memory device by forming a conductive layer for floating gates, made of single crystalline material, over a semiconductor substrate.

A method of manufacturing a nonvolatile memory device according to an aspect of the disclosure includes forming a tunnel insulating layer over a semiconductor substrate; forming tunnel insulating patterns to expose portions of the semiconductor substrate by removing portions of the tunnel insulating layer formed over isolation regions of the semiconductor substrate; forming a first conductive layer of single crystalline material over the tunnel insulating patterns and the exposed portions of the semiconductor substrate; and forming a second conductive layer over the first conductive layer.

After forming the second conductive layer, the method further preferably includes forming hard mask patterns on the second conductive layer, wherein the hard mask patterns expose portions of the second conductive layer in the isolation regions; performing an etch process on the second conductive layer, the first conductive layer, the tunnel insulating layer, and the semiconductor substrate using the hard mask patterns to form trenches in the respective isolation regions; and filling the trenches with an insulating layer to form isolation layers.

The first conductive layer preferably is formed using a selective epitaxial growth method.

The first conductive layer preferably comprises a single doped silicon layer.

The first conductive layer preferably fully covers the tunnel insulating layer.

The method preferably further includes performing a polishing process to flatten a top surface of the first conductive layer, after forming the first conductive layer.

The first conductive layer and the second conductive layer preferably together form floating gates.

The width of an opening portion of each of the tunnel insulating patterns preferably is identical to or narrower than the width of each of the isolation regions.

A nonvolatile memory device according to another aspect of the disclosure includes tunnel insulating patterns formed over a semiconductor substrate; a first conductive layer of single crystalline material formed over the tunnel insulating patterns; and a second conductive layer formed over the first conductive layer.

The first conductive layer preferably is formed using a selective epitaxial growth method.

The first conductive layer preferably comprises a single doped silicon layer.

The first conductive layer and the second conductive layer preferably together form floating gates.

A method of manufacturing a nonvolatile memory device according to yet another aspect of the disclosure includes forming a tunnel insulating layer over a semiconductor substrate; exposing portions of the semiconductor substrate by removing portions of the tunnel insulating layer formed in isolation regions; forming a first conductive layer over the exposed portions of the semiconductor substrate using a selective epitaxial growth method, wherein the first conductive layer fully covers the exposed portions of the semiconductor substrate and a top surface of the tunnel insulating layer; performing an etch process to flatten a top surface of the first conductive layer; and forming a second conductive layer on the flat top surface of the first conductive layer to form floating gates formed of the first and second conductive layers together.

After forming the floating gates, the method preferably further includes forming hard mask patterns, opening the isolation regions over the second conductive layer and removing portions of the second conductive layer, the first conductive layer, the tunnel insulating layer, and the semiconductor substrate by performing an etch process using the hard mask patterns as an etch mask to form trenches.

The width of an opening portion of each of the tunnel insulating patterns preferably is identical to or narrower than the width of each of the isolation regions.

The etch process preferably is performed using a chemical mechanical polishing process.

The first conductive layer preferably comprises a single doped silicon layer.

### BRIEF DESCRIPTION OF THE DRAWINGS

FIGS. 1A to 1H are cross-sectional views illustrating a method of manufacturing a nonvolatile memory device according to an exemplary embodiment of this disclosure.

### DESCRIPTION OF EMBODIMENT

Hereinafter, an exemplary embodiment of the disclosure is described in detail with reference to the accompanying drawings. The drawing figures are provided to allow those having ordinary skill in the art to understand the scope of the embodiment of the disclosure.

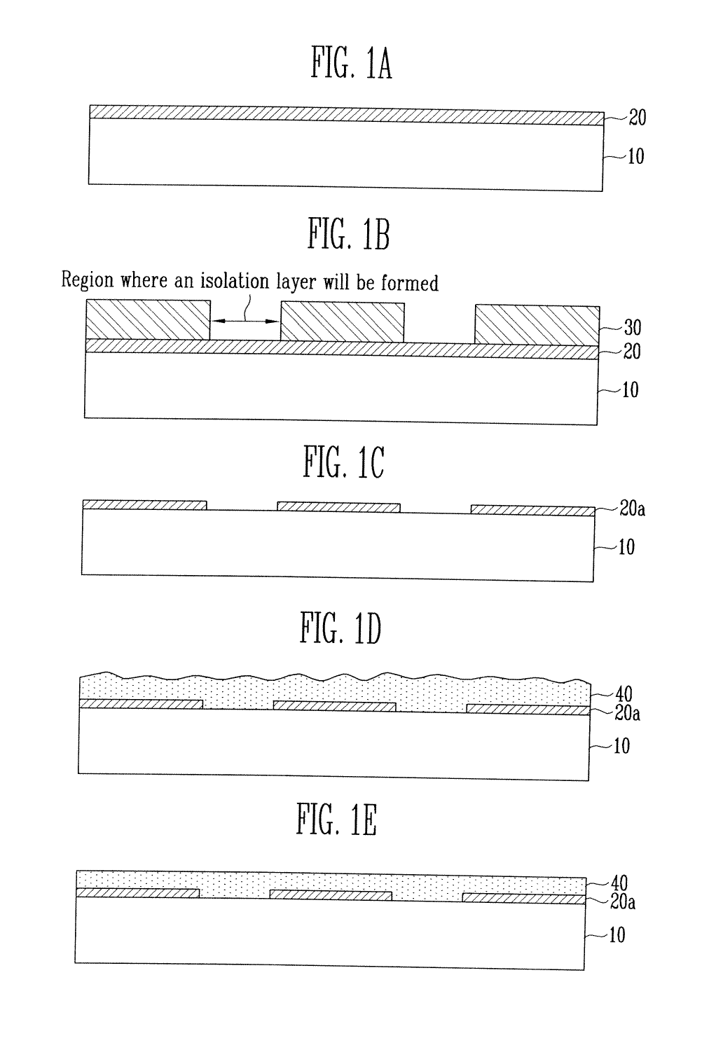

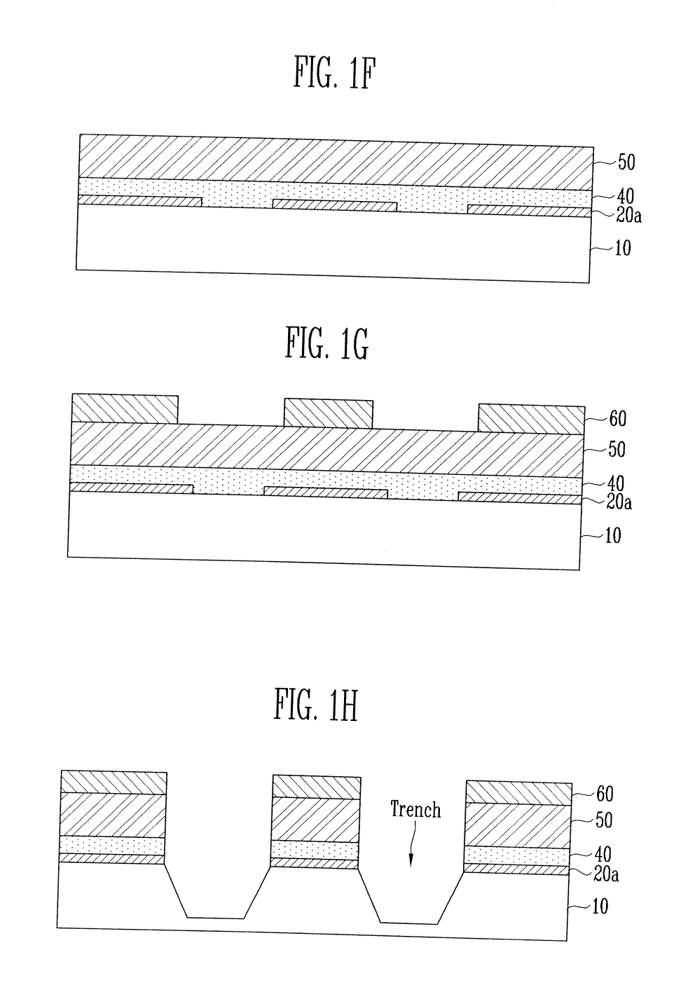

FIGS. 1A to 1H are cross-sectional views illustrating a method of manufacturing a nonvolatile memory device according to an exemplary embodiment of this disclosure.

Referring to FIG. 1A, a tunnel insulating layer 20 is formed over a semiconductor substrate 10 (for example, a silicon substrate). The tunnel insulating layer 20 preferably is an oxide layer or an oxynitride layer. For example, an oxide layer may be formed over the semiconductor substrate 10, and a silicon nitride layer may be formed by combining nitrogen (N) and the oxide layer. In this case, the charge breakdown (Q_{bd}), FN, stress, hot carrier injection, and endurance characteristics of the nonvolatile memory device can be improved.

Referring to FIG. 1B, photoresist patterns 30 are formed over the tunnel insulating layer 20. Here, regions in which respective isolation layers will be formed are exposed in the photoresist patterns 30.

Referring to FIG. 1C, a first etch process for removing the tunnel insulating layer 20 exposed through the photoresist patterns 30 is performed, thereby forming tunnel insulating patterns 20a. The first etch process preferably is performed by a dry etching process. In particular, the width of an opening portion of the tunnel insulating pattern 20a preferably is identical to or narrower than the width of the isolation layer to be formed later. Next, the remaining photoresist patterns 30 are removed.

Referring to FIG. 1D, a first conductive layer 40 for floating gates is selectively formed over the semiconductor substrate 10 exposed through the tunnel insulating patterns 20a. The first conductive layer 40 is formed of single crystalline material, preferably using a single doped selective epitaxial growth (D-SEG) method. Here, the thickness of the first conductive layer 40 might not be regular because of the tunnel insulating patterns 20a and the selective epitaxial growth method. The epitaxial layer preferably fully covers the tunnel insulating layer 20 and preferably has a height higher than a desired target.

Referring to FIG. 1E, a chemical mechanical polishing (CMP) process or other suitable process may be performed on the first conductive layer 40 having an irregular thickness, thereby flattening a top surface of the first conductive layer 40.

Referring to FIG. 1F, a second conductive layer 50 for the floating gates is formed on the first conductive layer 40. The second conductive layer 50 preferably is formed using a doped polysilicon layer as a dopant.

Referring to FIG. 1G, hard mask patterns 60 are formed in the active regions of memory cells over the second conductive layer 50. Here, regions in which the isolation layers will be formed are exposed through the hard mask patterns 60.

Referring to FIG. 1H, a second etch process is performed on the second conductive layer 50, the first conductive layer 40, the tunnel insulating patterns 20a, and the semiconductor substrate 10 using the hard mask patterns 60, thereby forming trenches in the respective regions in which the isolation layers will be formed. The second etch process preferably is performed by a dry etching process.

Although not shown, the nonvolatile memory device may be formed in such a manner that an insulating layer is formed within the trenches for the isolation layers, thereby forming the isolation layers, and then forming a dielectric layer (not shown) and a conductive layer (not shown) for control gates.

According to the disclosure, the first conductive layer is formed of the conductive layer of single crystalline material. Accordingly, a shift in the threshold voltage of a memory cell due to the grain size may be prohibited, and so the electrical and cycling characteristics of a nonvolatile memory device may be improved.

What is claimed is:

1. A method of manufacturing a nonvolatile memory device, comprising:
forming a tunnel insulating layer over a semiconductor substrate;
forming tunnel insulating patterns to expose portions of the semiconductor substrate by removing portions of the tunnel insulating layer formed over isolation regions of the semiconductor substrate;
forming a first conductive layer of single crystalline material over the tunnel insulating patterns and exposed portions of the semiconductor substrate; and
forming a second conductive layer over the first conductive layer.

2. The method of claim 1, further comprising, after forming the second conductive layer:
forming hard mask patterns on the second conductive layer, wherein the hard mask patterns expose portions of the second conductive layer in the isolation regions;
performing an etch process on the second conductive layer, the first conductive layer, the tunnel insulating patterns, and the semiconductor substrate using the hard mask patterns to form trenches in the isolation regions; and
filling the trenches with an insulating layer to form isolation layers.

3. The method of claim 1, comprising forming the first conductive layer using a selective epitaxial growth method.

4. The method of claim 1, comprising forming the first conductive layer of a single doped silicon layer.

5. The method of claim 1, wherein the first conductive layer fully covers the tunnel insulating patterns.

6. The method of claim 1, further comprising performing a polishing process to make a flat top surface of the first conductive layer, after forming the first conductive layer.

7. The method of claim 1, wherein the first conductive layer and the second conductive layer together form floating gates.

8. The method of claim 1, wherein a width of an opening portion of each of the tunnel insulating patterns is identical to or narrower than a width of each of the isolation regions.

9. A nonvolatile memory device, comprising:
tunnel insulating patterns formed over a semiconductor substrate;
a first conductive layer of single crystalline material formed over the tunnel insulating patterns; and
a second conductive layer formed over the first conductive layer.

10. The nonvolatile memory device of claim 9, wherein the first conductive layer is formed using a selective epitaxial growth method.

11. The nonvolatile memory device of claim 9, wherein the first conductive layer comprises a single doped silicon layer.

12. The nonvolatile memory device of claim 9, wherein the first conductive layer and the second conductive layer together form floating gates.

13. A method of manufacturing a nonvolatile memory device, comprising:
forming a tunnel insulating layer over a semiconductor substrate;
exposing portions of the semiconductor substrate by removing portions of the tunnel insulating layer formed over isolation regions of the semiconductor substrate;
forming a first conductive layer over the exposed portions of the semiconductor substrate using a selective epitaxial growth method, wherein the first conductive layer fully covers the exposed portions of the semiconductor substrate and a top surface of the tunnel insulating layer;
performing an etch process to flatten a top surface of the first conductive layer; and
forming a second conductive layer on the flat top surface of the first conductive layer to form floating gates from the first and second conductive layers together.

14. The method of claim 13, further comprising after forming the floating gates:
forming hard mask patterns exposing the isolation regions over the second conductive layer; and
removing portions of the second conductive layer, the first conductive layer, the tunnel insulating layer, and the semiconductor substrate by performing an etch process using the hard mask patterns as an etch mask to form tranches.

15. The method of claim 13, wherein a width of an opening portion of the tunnel insulating layer, after removing portions of the tunnel insulating layer, is identical to or narrower than a width of each of the isolation regions.

16. The method of claim 13, comprising performing the etch process using a chemical mechanical polishing process.

17. The method of claim 13, wherein the first conductive layer comprises a single doped silicon layer.
